(19) United States
(12) Patent Application Publication
(10) Pub. No.: US 2005/0054204 A1
(43) Pub. Date: Mar. 10, 2005

(54) Method of rounding top corner of trench

(76) Inventor: Chien-An Yu, Taipei County (TW)

Correspondence Address: QUINTERO LAW OFFICE, 1617 BROADWAY, 3RD FLOOR, SANTA MONICA, CA, 90404, US

(21) Appl. No.: 10/727,846

(22) Filed: Dec. 4, 2003

(30) Foreign Application Priority Data
Sep. 4, 2003 (TW) 92124435

(51) Int. Cl. H01L 21/311

(52) U.S. Cl. 438/700

(57) ABSTRACT

A method for rounding the top corner of a trench. A masking layer is formed on a substrate, and the masking layer is then patterned to form at least one opening therein to expose the substrate and form a recess region in the substrate. The recess region is oxidized to form a first oxide layer to round the top corner of the recess region. The first oxide layer and the substrate under the opening are successively etched to form a trench in the substrate. A second oxide layer is conformably formed on the surface of the trench. A method for forming a shallow trench isolation structure is also disclosed.

### BACKGROUND OF THE INVENTION

1. Field of the Invention

The present invention relates in general to the shallow trench isolation (STI) process, and more particularly, to a method for rounding the top corner of a trench and a method for forming a STI structure.

2. Description of the Related Art

Recently, as the manufacturing techniques of semiconductor integrated circuits have developed, the number of elements in a chip has increased. Accordingly element size decreases as the degree of integration increases. The line width used in manufacturing lines has decreased from sub-micron to quarter-micron, or even to a smaller size. Regardless of the reduction in element size, however, adequate insulation or isolation must exist between individual elements in the chip to ensure optimal performance. This technique is called device isolation technology. The main object of said technology is to form an isolation region with reduced size capable of excellent isolation, while leaving as much available area as possible on the chip surface for integration of more elements.

Among different element isolation techniques, local oxidation of silicon (LOCOS) and shallow trench isolation (STI) are the two most used methods. In particular, as the latter offers a small isolation region and can maintain a flat substrate surface after fabrication it is the prevailing manufacturing method.

The conventional method for forming shallow trench isolation structure is shown in the cross-sections of FIGS. 1a to 1d. In FIG. 1a, a masking layer 105 and a boron silicate glass (BSG) layer 106 are sequentially formed on a silicon substrate 100. The masking layer 105 can be composed of a pad oxide layer 102 and a silicon nitride layer 104 thereon. Thereafter, a photoresist layer 108 is coated on the BSG layer 106 and subsequently patterned using lithography to expose the portion where the element isolation region is to be formed. Next, the BSG layer 106 is etched using the photoresist layer 108 as a mask to form an opening 110 therein.

Next, in FIG. 1b, after the photoresist layer 108 is removed, the masking layer 105 and the silicon substrate 100 under the opening 110 are etched using the BSG layer 106 as a mask to form a trench 112 in the substrate 100 to define the active area (AA) of the element.

Next, in FIG. 1c, after the BSG layer 106 is removed, the opening sidewall of the masking layer 105 is etched to expose the top corner 114 of the trench 112. Next, thermal oxidation is performed to grow a thin silicon oxide layer 116 as the liner oxide layer on the surface of the trench 112.

Thereafter, high density plasma chemical vapor deposition (HDPCVD) is performed to form a silicon oxide layer (not shown) on the masking layer 105 and fill the trench 112. Next, chemical mechanical polishing (CMP) is performed, whereby the excess oxide layer on the masking layer 105 is removed to leave a portion of silicon oxide layer 118 in the trench 112.

Finally, in FIG. 1d, the silicon nitride layer 104 and the pad oxide layer 102 are removed and a portion of the remaining silicon oxide layer 118 is etched to complete the shallow trench isolation structure 118a with a flat surface. When the liner oxide layer 116 is formed, however, the stress is concentrated on the top corner 114 of the trench 112, reducing the growing speed of the liner oxide layer 116 at the top corner 114 of the trench 112, so that the top corner 114 of the trench 112 cannot be effectively rounded. As a result, during device is operation, electric field is easily concentrated at the top corner 114 of the trench 114, inducing current leakage and reduces device reliability.

### SUMMARY OF THE INVENTION

Accordingly, an object of the present invention is to provide a method for rounding the top corner of a trench and a method for forming a shallow trench isolation structure, which employs oxidation performed on a substrate prior to trench etching, thereby rounding the top corner of the subsequent trench by the bird's beak effect to increase device reliability.

Another object of the present invention is to provide a novel method for rounding the top corner of a trench and a method for forming a shallow trench isolation structure, in which trench etching is performed subsequent to oxidation of a recess region formed on a substrate, thereby preventing the active area from narrowing.

According to the object of the invention, a method for rounding the top corner of a trench is provided. First, a masking layer is formed on a substrate. Next, the masking layer is patterned to form at least one opening therein to expose the substrate and form a recess region in the substrate. Next, the recess region is oxidized forming a first oxide layer thereon to round the top corner of the recess region. Next, the first oxide layer and the substrate under the opening are successively etched to form the trench in the substrate. Finally, a second oxide layer is conformably formed on the surface of the trench.

The recess region has a depth of about 100 to 300 Å.

Moreover, the recess region is oxidized by rapid thermal oxidation (RTO) at a temperature of about 950 to 1200° C. for 20 to 60 sec.

Moreover, the first oxide layer has a thickness of about 70 to 100 Å and the second oxide layer has a thickness of about 110 to 140 Å.

Additionally, according to the object of the invention, a method for forming a shallow trench isolation structure is provided. First, a pad oxide layer, a silicon nitride layer, and a boron silicate glass layer are successively formed overlying a substrate. Next, the boron silicate glass layer, the silicon nitride layer, and the pad oxide layer are successively etched to form at least one opening therein to expose the substrate and form a recess region in the substrate. Thereafter, the recess region is oxidized by thermal oxidation to form a first oxide layer thereon to round the top corner of the recess region. Next, the first oxide layer and the substrate under the opening are successively etched to form a trench in the substrate. Next, the boron silicate glass layer is removed and a portion of the opening in the sidewalls of the silicon nitride layer and the pad oxide layer is removed. Finally, a second oxide layer is conformably formed on the surface of the trench and then the trench is filled with an insulating layer to form the shallow trench isolation structure.

The portion of the opening in the sidewalls of the silicon nitride layer and the pad oxide layer can be removed by hydrofluoric acid (HF) or ethylene glycol (EG) solution.

Moreover, the recess region has a depth of about 100 to 300 Å.

Moreover, the recess region is oxidized by rapid thermal oxidation (RTO) at a temperature of about 950 to 1200° C. for 20 to 60 sec.

Moreover, the first oxide layer has a thickness of about 70 to 100 Å and the second oxide layer has a thickness of about 110 to 140 Å.

### DESCRIPTION OF THE DRAWINGS

The present invention will become more fully understood from the detailed description given hereinbelow and the accompanying drawings, given by way of illustration only and thus not intended to be limitative of the present invention.

FIGS. 1a to 1d are cross-sections showing a conventional method for forming a shallow trench isolation structure.

FIGS. 2a to 2f are cross-sections showing a method for forming a shallow trench isolation structure according to the invention.

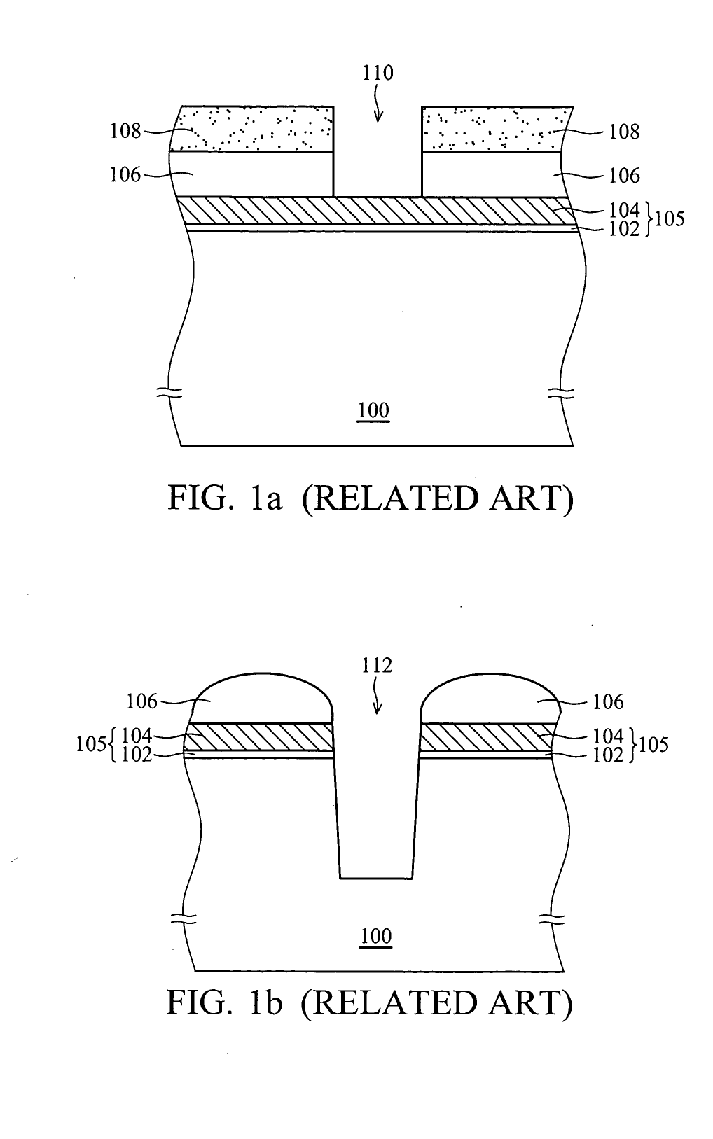

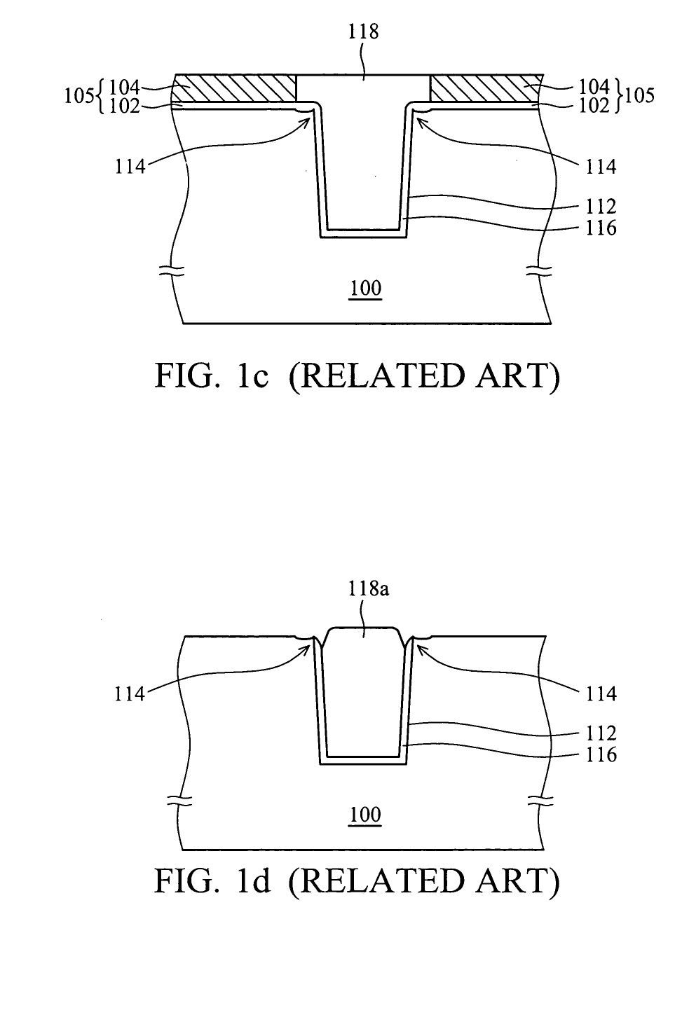

### DETAILED DESCRIPTION OF THE INVENTION

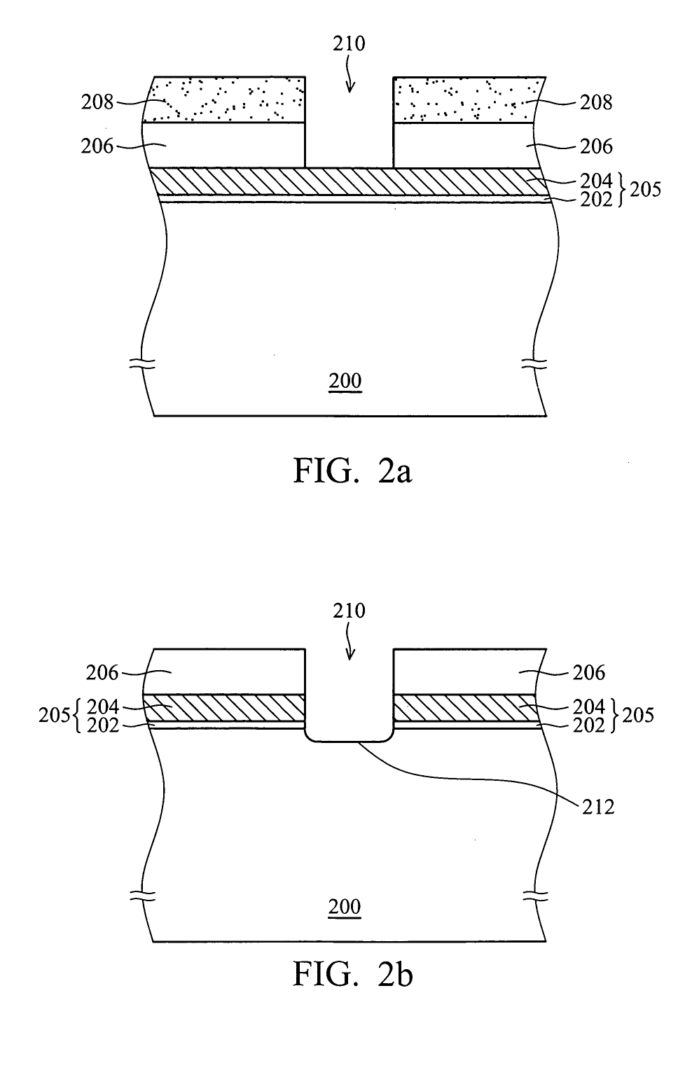

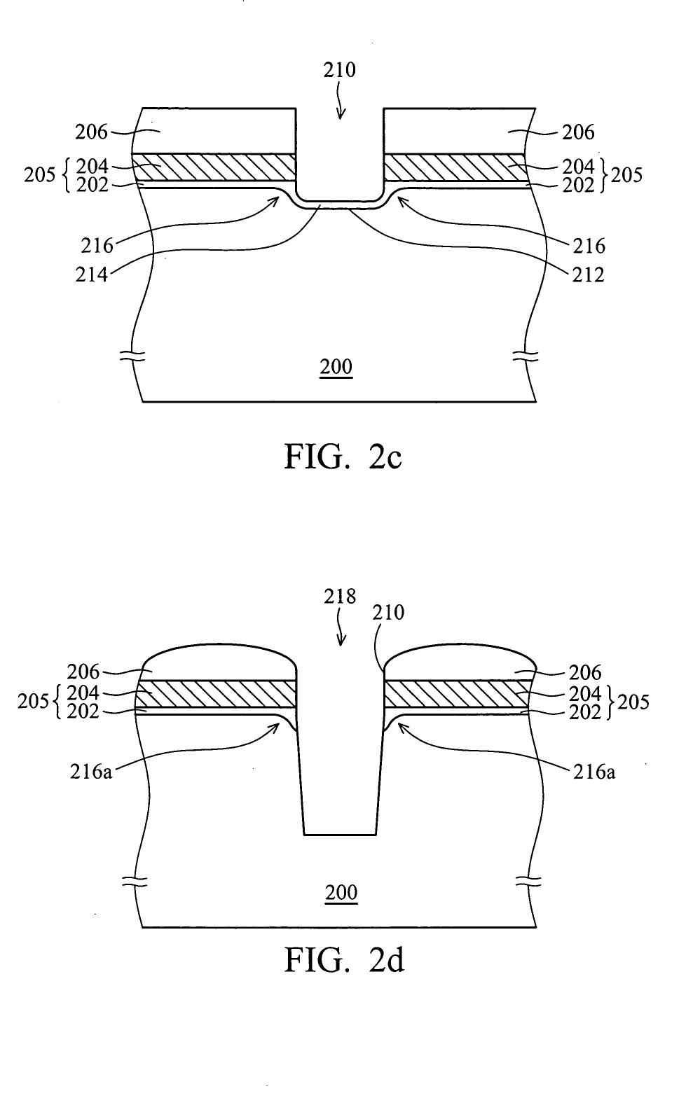

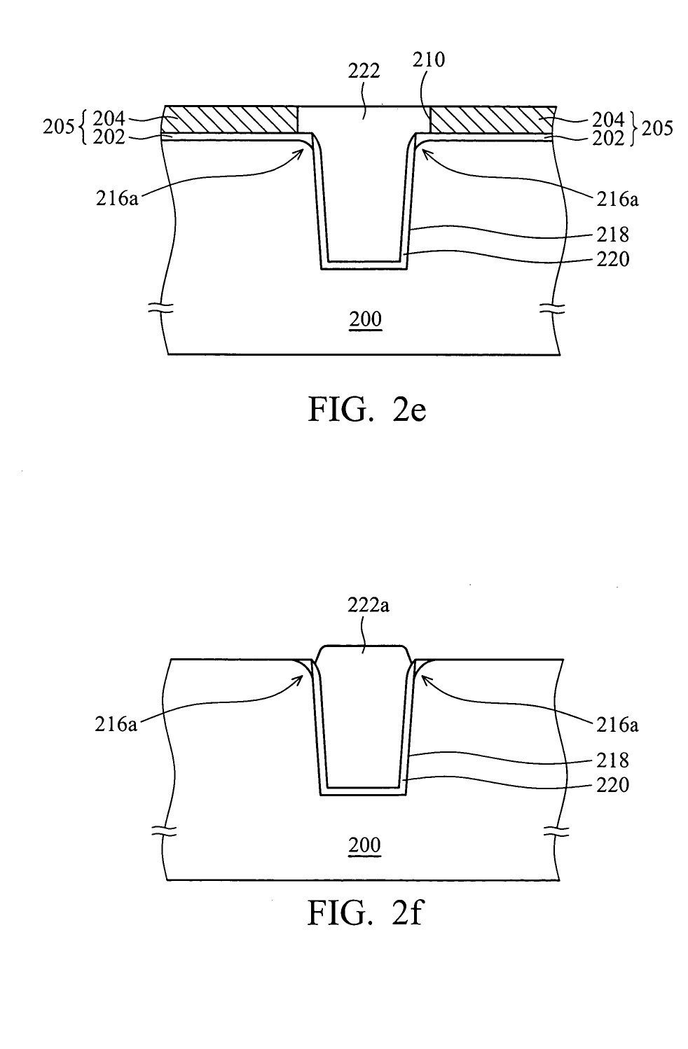

FIGS. 2a to 2f are cross-sections showing a method for forming a shallow trench isolation structure according to the invention. First, in FIG. 2a, a substrate 200, such as a silicon substrate or other semiconductor substrate, is provided. Next, a masking layer 205 is formed on the substrate 200, which can be composed of a single layer or multiple layers. In this invention, the masking layer 205 is preferably composed of a pad oxide layer 202 and a relatively thicker silicon nitride layer 204 thereon.

Next, a boron silicate glass (BSG) layer 206 and a photoresist layer 208 are successively formed on the masking layer 205. Here, the BSG layer 206 is used as a mask for defining the underlying masking layer 205. Next, conventional lithography is performed on the photoresist layer 208 to form at least one opening therein to expose the BSG layer 206, where a shallow trench isolation region is to be formed through the opening. Thereafter, anisotropic etching, such as a reactive ion etching (RIE), is performed using the patterned photoresist layer 208 with the opening as a mask to form an opening 210 in the BSG layer 206.

Next, in FIG. 2b, after the patterned photoresist layer 208 is removed by ashing or other suitable method, the masking layer 205 is etched using the BSG layer 206 as a mask to expose the substrate 200 under the opening 210. Meanwhile, the exposed substrate 200 is etched to form a recess region 212 with a depth of about 100 to 300 Å therein.

Next, a critical step of the invention is performed. In FIG. 2c, the recess region 212 is oxidized to form a thin oxide layer 214 thereon. In the invention, the thin oxide layer 214 has a thickness of about 70 to 100 Å. Moreover, the recess region 212 can be oxidized by rapid thermal oxidation (RTO) at a temperature of about 950 to 1200° C. for 20 to 60 sec. During oxidation of the recess region 212, oxygen laterally diffuses from the top corner 216 of the recess region 212 to induce the bird's beak effect. As a result, the top corner 216 of the recess region 212 can be effectively rounded, as shown in FIG. 2c.

Next, in FIG. 2d, anisotropic etching, such as RIE, is performed using the BSG layer 206 as a mask to successively etch the oxide layer 214 and the substrate 200 under the opening 210 to a predetermined depth, thereby forming a trench 218 in the substrate 200. Here, the trench 218 with a rounded top corner 216a is used for active area (AA) definition and has a depth of about 2500 to 3000 Å.

Next, in FIG. 2e, the BSG layer 206 is removed. Thereafter, a portion of the opening sidewall of the masking layer 205 is removed to expose the rounded top corner 216a of the trench 218. In the invention, the portion of the opening sidewall of the masking layer 205 can be removed by hydrofluoric acid (HF) or ethylene glycol (EG) solution.

Next, a thin oxide layer 220 is conformably formed on the surface of the trench 218 to serve as a liner oxide layer. Here, the liner oxide layer 220 can be formed by thermal oxidation or other deposition, for example, CVD, and has a thickness of about 110 to 140 Å. Preferably, the liner oxide layer 220 is formed by thermal oxidation, thereby repairing the defects formed in the trench 218 during etching.

Next, an insulating layer (not shown) is formed on the masking layer 205 and fills the trench 218. Here, the insulating layer can be an oxide layer formed by high-density plasma CVD (HDPCVD). Thereafter, the excess insulating layer on the masking layer 205 is removed by an etching back process or chemical mechanical polishing (CMP) to leave a portion of the insulating layer 222 in the trench 218 only.

Finally, in FIG. 2f, the masking layer 205 is removed. The method of removing the silicon nitride layer 204, can, for example use soaking with hot H₃PO₄ solution. Moreover, the method of removing pad oxide layer 202 can, for example, use soaking with HF acid solution. At the same time, the remaining insulating layer 222 is partially etched to form the shallow trench isolation structure 222a.

According to the invention, oxidation is performed before trench etching, thereby inducing the bird's beak effect so that subsequent trenches have a rounded top corner. Accordingly, compared with the conventional method for rounding the top corner of the trench, the invention can more effectively round the top corner of the trench, thereby preventing current leakage during device operation. That is, device reliability can be increased according to the invention.

Moreover, by oxidizing a recess region formed on a substrate, narrowing of the active area after etching can be prevented, thereby maintaining the electrical properties of the device.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation to encompass all such modifications and similar arrangements.

1. A method for rounding the top corner of a trench, comprising the steps of:
forming a masking layer overlying a substrate;
patterning the masking layer to form at least one opening therein to expose the substrate and form a recess region in the substrate;
oxidizing the recess region to form a first oxide layer thereon to round the top corner of the recess region;
successively etching the first oxide layer and the substrate under the opening to form the trench in the substrate; and
conformably forming a second oxide layer on the surface of the trench.

2. The method as claimed in claim 1, wherein the masking layer comprises a pad oxide layer and a silicon nitride layer thereon.

3. The method as claimed in claim 1, wherein the step of patterning the masking layer further comprises:
successively forming a boron silicate glass layer and a photoresist layer on the masking layer;
patterning the photoresist layer to form at least one second opening therein to expose the boron silicate glass layer;
etching the exposed boron silicate glass layer to expose the masking layer;
removing the patterned photoresist layer; and
etching the masking layer using the boron silicate glass layer as a mask.

4. The hard mask structure as claimed in claim 1, further removing a portion of the opening in the sidewall of the masking layer before the second oxide layer is formed.

5. The method as claimed in claim 4, wherein the portion of the opening sidewall of the masking layer is removed by hydrofluoric acid (HF) or ethylene glycol (EG) solution.

6. The method as claimed in claim 1, wherein the recess region has a depth of about 10 to 300 Å.

7. The method as claimed in claim 1, wherein the recess region is oxidized by rapid thermal oxidation.

8. The method as claimed in claim 7, wherein the recess region is oxidized at a temperature of about 950 to 1200° C.

9. The method as claimed in claim 7, wherein the recess region is oxidized for 20 to 60 sec.

10. The method as claimed in claim 1, wherein the first oxide layer has a thickness of about 70 to 100 Å.

11. The method as claimed in claim 1, wherein the second oxide layer is formed by thermal oxidation.

12. The method as claimed in claim 1, wherein the second oxide layer has a thickness of about 110 to 140 Å.

13. A method for forming a shallow trench isolation structure, comprising the steps of:
successively forming a pad oxide layer, a silicon nitride layer, and a boron silicate glass layer overlying a substrate;
successively etching the boron silicate glass layer, the silicon nitride layer, and the pad oxide layer to form at least one opening therein to expose the substrate and form a recess region in the substrate;
oxidizing the recess region by thermal oxidation to form a first oxide layer thereon to round the top corner of the recess region;
successively etching the first oxide layer and the substrate under the opening to form a trench in the substrate;
conformably forming a second oxide layer on the surface of the trench; and
filling the trench with an insulating layer to form the shallow trench isolation structure.

14. The method as claimed in claim 13, before forming the second oxide layer, further comprising the step of:
removing the boron silicate glass layer; and
removing a portion of the opening in the sidewalls of the silicon nitride layer and the pad oxide layer.

15. The method as claimed in claim 14, wherein the portion of the opening in the sidewalls of the silicon nitride layer and the pad oxide layer is removed by hydrofluoric acid or ethylene glycol solution.

16. The method as claimed in claim 13, wherein the recess region has a depth of about 10 to 300 Å.

17. The method as claimed in claim 13, wherein the recess region is oxidized at a temperature of about 950 to 1200° C.

18. The method as claimed in claim 13, wherein the recess region is oxidized for 20 to 60 sec.

19. The method as claimed in claim 13, wherein the first oxide layer has a thickness of about 70 to 100 Å.

20. The method as claimed in claim 13, wherein the second oxide layer has a thickness of about 110 to 140 Å.
